(19) United States
(12) Patent Application Publication
(10) Pub. No.: US 2017/0288561 A1
(43) Pub. Date: Oct. 5, 2017

(54) Microgrid Power Architecture

(71) Applicant: Ideal Power Inc., Austin, TX (US)

(72) Inventors: Nicholas A. Lemberg, Austin, TX (US); Lawrence M. Hoskins, Austin, TX (US); Guy Michael Barron, Austin, TX (US)

(73) Assignee: Ideal Power, Inc., Austin, TX (US)

(21) Appl. No.: 15/474,944

(22) Filed: Mar. 30, 2017

Related U.S. Application Data
(60) Provisional application No. 62/315,447, filed on Mar. 30, 2016.
(60) Provisional application No. 62/326,660, filed on Apr. 22, 2016.
(60) Provisional application No. 62/326,662, filed on Apr. 22, 2016.
(60) Provisional application No. 62/329,052, filed on Apr. 28, 2016.
(60) Provisional application No. 62/360,860, filed on Jul. 11, 2016.
(60) Provisional application No. 62/360,783, filed on Jul. 11, 2016.
(60) Provisional application No. 62/360,798, filed on Jul. 11, 2016.
(60) Provisional application No. 62/360,682, filed on Jul. 11, 2016.
(60) Provisional application No. 62/457,037, filed on Feb. 9, 2017.

(51) Int. Cl. H02M 5/293; H02M 1/084; G01R 21/00; H02M 1/32

(52) U.S. Cl. CPC H02M 5/293; H02M 1/32; H02M 1/084; G01R 21/007; H02M 2005/2932

(57) ABSTRACT

Power converters, and microgrids driven by such a power converter, in which the converter is controlled by a proportional controller which operates directly on AC waveforms, preferably without conversion to a DC type signal; preferably with use of voltage compensation to remove inherent error of proportional controller; and preferably with use of individual phase RMS voltages in the voltage compensation, to allow for normal operation under any load condition. Undervoltage of one or two phases is automatically compensated by adjusting the voltage of all phases, to retain balance. Line-starting of a motor load is automatically detected, and frequency droop is driven, apart from the other control relations in the system, to complete the line-starting operation as quickly as possible.

### CROSS-REFERENCE

Priority is claimed from U.S. provisional applications 62/315,447, 62/326,660, 62/326,662, 62/329,052, 62/360,783, 62/360,798, 62/360,860, and 62/360,682, all of which are hereby incorporated by reference.

### BACKGROUND

The present application relates to control of microgrid power networks and converters.

Note that the points discussed below may reflect the hindsight gained from the disclosed inventions, and are not necessarily admitted to be prior art.

### BACKGROUND

### Microgrids

An important area of technology development has been microgrids, where loads are supplied independently of the large-scale electric power grid. The term “microgrid” is used, in this application, to refer to local power networks which include both sources and loads, and which are at least sometimes isolated from the larger power grids of regional or continental scale. Typically a microgrid will not extend across a distance of more than a few kilometers, and often much less. Microgrids will often include an optional connection to the larger power grid.

The full electric power grid may contain power sources of the order of gigawatts, but in many cases much smaller supplies can be locally useful. Such smaller “backup” power sources have long been an important tool of power engineering. Today, most of the installations where backup power supplies have traditionally been used are migrating to microgrids, i.e. to a more controlled and more comprehensively engineered power supply architecture. For one example, a rural community which is subject to uncontrollable disconnection from the power grid may have backup generators which can supply power, at higher marginal cost, when the grid connection fails. Microgrid functionality, in such a case, can provide stable and balanced supply from the local source to the local loads when the grid connection is down, as well as improved power regulation when the grid connection is active, and blinkless reconnect when grid power is restored. For another example, hospitals commonly have backup generators which are at least large enough to power operating rooms and life support, and possibly the whole hospital, if grid power fails. For another example, the onboard power needs in a large ship or offshore platform can be thought of as a microgrid application. For another example, project development in very remote locations (such as islands) will often require construction of a microgrid. For another example, businesses which support green energy, or have buildings in locations where green energy is economically attractive, may include local sourcing of power from battery banks which are fed by solar panels or wind generators.

As battery storage has become cheaper per kW-hour, battery banks have come to provide a more important adjunct to backup generators. Moreover, as many business operations have been geographically extended to (or subjected to) declining infrastructure, the capital cost of local power supply has become more attractive in many cases. This can permit business operations to withstand power outages or brownouts, which have become increasingly common in many areas.

This trend has been accelerated by the availability of a “universal” power converter, with the advent of power-packet-switching-architecture converters (“PPSA” converters). These converters permit not only voltage conversion, but also frequency conversion, power factor correction, multiphase conversion, phase shift, inversion from DC, and many other functions.

The 30B power converter, from Ideal Power Inc., was shipped before the priority date of the present application. This power converter included a pure proportional innermost control loop, which provided fast adjustment of the instantaneous value of the output voltage on each phase, as that target value varied during the period of the power line frequency. However, that converter did not include any way to correct the nonzero persistent error which is characteristic of pure proportional control systems.

### Islanded Microgrids

A microgrid which is not connected to a larger grid is referred to as “islanded.” When a microgrid is islanded, it may be desired to bring an additional power source online, e.g. due to demand changes with time of day. If both power sources are connected to the grid through a smart power converter, this can have some surprising difficulties.

There is a settling time associated with a converter joining an islanded microgrid system, due to the converter offloading demand from the converter(s) which are already operating. This shift results in all converters settling on a new power demand.

### BACKGROUND

### Starting Electric Motors

The simplest way to start a small motor is “line-starting,” i.e. just connect the motor terminals directly to the (low-voltage) power supply lines. Line-starting motors is challenging to the utility network. The “inrush” current, when a motor is started from line voltage, can exceed the nameplate values by 5× or more. Thus, e.g., a 50 A motor would command something in the range of 250 A to 350 A at startup. Moreover, these inrush currents are almost purely reactive, and the high-current condition can persist for a second or longer.

Where the power supply comes from the utility grid, such a transient overcurrent can typically be tolerated by the transformer which steps down the electrical supply to the customer's meter, and slow-blow fuses or breakers are commonly used on the customer side to avoid tripping during this inrush. Thus, this inrush current is a manageable challenge where power is drawn from the grid. However, these transient overcurrents can present a more significant problem in microgrids, particularly where the power supply is drawn through one or more electronic power converters. For example, connecting a 50 A motor to a network with 150 A current limit would be problematic, as the microgrid source(s) would not be able to supply the required current.

Conventional induction motor controllers (“VFDs”) typically vary both voltage and frequency for more effective motor control. Once the motor has come up to speed, the synchronized motor speed is directly related to excitation frequency (or line frequency less a small amount of slippage).

### Microgrid Architecture with Proportional Control of AC Voltage (IPC-276)

The present application teaches, among other innovations, a microgrid architecture where power is supplied to the microgrid through one or more electronic power converters. The power converters are controlled using a control architecture in which the inner loop is a proportional control loop which can work directly with the AC voltage waveforms (and any additional harmonic content present on the output terminals of the converter). To overcome the inherent offset error in the proportional controller, RMS voltage compensation is wrapped around the proportional controller loop. The RMS voltage compensation loop includes integration, and can optionally be a “PI” (proportional/integral) or “PID” (proportional/integral/differential) loop. The integrated result from the voltage compensation loop is added back into the reference RMS value to create RMS command values, which are then converted to AC waveforms for use in the proportional controller.

A further innovative feature is that the RMS voltage compensation scheme is independently applied to each of the individual phases; this allows unbalanced loads to be connected to the microgrid without creating unbalanced output voltages.

### Microgrid Architecture With Sine Wave Current Limiting (IPC-281)

The microgrid power converter described below has the ability to work with sine wave quantities. One innovative aspect of this is the use of Sine Wave Current Limiting. This is an overcurrent protection procedure which works on AC quantities (sine waves) instead of DC quantities.

Traditionally all limits are “hard” limits; if a commanded value exceeds the limit, the output cannot rise above the limit. Using this sort of scheme on a sine wave results in the truncation of the top of the sine wave, creating a trapezoidal waveform while leaving the ‘sides’ of the sine wave intact. This is no longer a sine wave, and its spectrum will include many higher-frequency components; the flat top on the waveform is typical of “clipping,” and introduces significant nonlinearity.

By contrast, the disclosed Sine Wave Current Limiting is applied to all portions of the sine wave equally. This creates a current limited sine wave, without clipping distortion, at the output of the converter.

In some embodiments (and most preferably), this current limiting method is applied both to combined RMS current (three phase current) and also to the individual single phases. In this case, the three phase limit is preferably favored over the single phase limits.

In some embodiments (and most preferably), Sine Wave Current Limiting control procedure is reinforced with an absolute limit for overload conditions that are not addressed with the sine wave limiting schemes.

### Microgrid Architecture with Voltage-Balancing Response to Phase Voltage Droop (IPC-282)

Another problem which can arise in power networks is phase imbalance, e.g. where one or two phases are seeing a fault, or where a heavy load has reduced one of the leg-to-leg or leg-to-ground impedances. The present application also teaches, among other innovations, a new way to maintain balance (same magnitude) between the three phase voltages of a microgrid during overcurrents of individual phases.

During overcurrent events (faults or overloads), an individual phase will enter current limiting, which results in a voltage sag on the current limited phase. To retain balance in this case, the present application also teaches that the voltages of the remaining phases are reduced to maintain balance. Note that, in this case, the new balanced magnitude is not the same as original balanced magnitude. This ensures that loads connected across all three phases will operate with a balanced input.

This method is particularly advantageous where some of the load units contain active power electronic converters, since these converters can simply compensate for the reduction in voltage (if sufficient total power is available), transparently to the final load.

Three phase motors can also benefit as they are intended to operate as balanced loads to maintain proper field excitation and rotation. Motor imbalance can degrade motor lifetime, especially if the motor is coupled to an element which has mechanical resonances at a relevant frequency.

The downside risk is that if the overload is severe enough and the corresponding voltage collapse deep enough the motor could fall out of synchronization with the line frequency due to a lack of available input energy.

### Microgrid Architecture with Startup Optimization (IPC-288)

Another innovative feature simplifies the process of bringing up an additional power source, which incorporates an electronic power converter, into an existing islanded microgrid. By preloading special values into control registers associated with the controller of the power supply which is being brought on, a quicker synchronization time is achieved. Surprisingly, the control register values which work best for this would correspond to an out-of-limits (overvoltage) condition if the system did not adapt. Upon turn on, the converter initially exports power during the settling time that occurs when joining the islanded system. As the system starts up, the control loops change the initial setpoints, so that the power converter never does actually output an overvoltage.

### Microgrid Architecture With Accelerated Frequency Droop (IPC-277)

As noted above, transient currents due to motor starting are a challenge for microgrid design. Among the inventions disclosed in the present application is a way to avoid overloading the electronic power converter when a transient inrush current occurs on the microgrid. According to the most preferred implementation, motor starting is sensed automatically, and the “superdroop” condition is initiated, when the ratio of reactive power to active power exceeds a target value. Upon initiation of the superdroop condition, the power frequency is promptly lowered down to its minimum value (e.g., in one example, to 60% of nominal power frequency). A lockout relation is also used to prevent the system from staying in the superdroop condition.

The drawback to this is that the balance of equipment on the microgrid will experience a frequency and voltage sag. In applications where this is tolerable, the superdroop method provides additional insurance against collapse of the microgrid network due to transient inrush current. Another advantage is that, for a given power converter rating, motors which are larger and/or more hard-starting (such as pump motors) can be used. Another advantage is that, for a given motor size limit in the microgrid, a lower-rated power converter can be used.

### Synergies and Advantages

The present application describes a number of inventions, as well as a preferred implementation in which all of these inventions are included. Moreover, the various combinations of these inventions combine together synergistically, and a number of additional advantages are present in the individual inventions and in the various subcombinations. According to various inventions, and the combination and subcombinations, thereof, advantages which are achieved include some or all of the following:
Microgrids which operate with balanced or unbalanced loads;
Microgrids which tolerate loads which induce harmonic distortion on the network;
Power converters which perform current limiting with reduced likelihood of generating distortion;
Microgrids which operate with bi-directional power flow;
Operation of multiple paralleled converters, which jointly provide voltage and frequency droop.

### Overview of Innovative Teachings

As noted above, the present application contains many innovative teachings which do not all have to be used together, and do not have to be used in the exact configuration shown. For quick reference, a few of these points are:
Operation of a power converter, and/or of a microgrid driven by such a power converter, in which a proportional controller operates directly on AC waveforms;
   preferably with no conversion to a DC type signal: RMS, DQ or other transforms; and
   preferably with use of voltage compensation to remove inherent error of proportional controller; and
   preferably with use of individual phase RMS voltages in the voltage compensation, to allow for normal operation under any load condition(s); and
   incorporation of a voltage and frequency droop capability in the above controller.
Power converters, and microgrids containing them, where undervoltage of one or two phases is automatically compensated by adjusting the voltage of all phases, to retain balance. This is particularly advantageous where a load element or a bridge to another microgrid may be drawing power through a PPSA or comparable electronic power converter.
Power converters, and microgrids containing them, where line-starting of a motor load is automatically detected, and where frequency droop is driven, apart from the other control relations in the system, to complete the line-starting operation as quickly as possible.
Power converters, and microgrids containing them, where the setpoints in a multilayer control architecture are preloaded, when the converter starts to feed power into an active microgrid, with values which would correspond to an overvoltage at the output of the converter. This is done within a control architecture which prevents the converter from ever actually outputting an overvoltage, but the preloading accelerates startup.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1 schematically shows firmware components of an electronic power supply controller, in a microgrid system, which includes several innovative features.

FIG. 2A shows how the firmware of FIG. 1 combines with hardware elements, in a sample embodiment.

FIG. 2B shows an example of implementation of the limiter block seen in FIGS. 1 and 2A.

FIG. 2C shows an example of implementation of the RMS calculation block, which was seen in FIGS. 1 and 2A.

FIG. 2D shows an example of implementation of the droop stages which were seen in FIGS. 1 and 2A.

FIG. 3 shows an example of how the microgrid system controller is combined with multiple power converter/supply units, and power supply lines, to form a complete microgrid.

FIG. 4A shows operation of a power converter, operated by a controller like that shown in FIGS. 1-2D, as various load types are successively added.

FIG. 4B is a graph of per-phase voltage and current, showing how the power converter responds to harmonic currents.

FIG. 4C shows operation of the converter during a transition out of regeneration.

FIG. 4D is a detail view of the transition from regeneration to loaded.

FIG. 4E is a plot of frequency and voltage, showing how two separate power converters in parallel, each operated by a controller like that illustrated in FIGS. 1-2D, reach convergence even when starting from different frequency setpoints. Note that this happens even without any intervention by a system controller like that shown in FIG. 3.

FIG. 4F shows that a mismatch in frequency setpoint can lead to asymmetrical load sharing.

FIG. 5 shows the difference between sine wave current limiting, as taught herein, and conventional hard current limiting.

FIGS. 6A-6D show how voltage balancing, implemented as described herein, permits graceful compensation for single-phase or two-phase overloads.

FIGS. 7A and 7B show how accelerated frequency droop is preferably used to enable faster recovery from an overcurrent due to line-starting a significantly large motor on the microgrid.

FIGS. 8A-8C show how the duration of transient instability is reduced, when an additional converter joins an islanded system, by modification of control parameters as described herein.

FIG. 9 shows an example of a power-packet-switching-architecture electronic power converter, including hardware components.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

### Architectural Overview

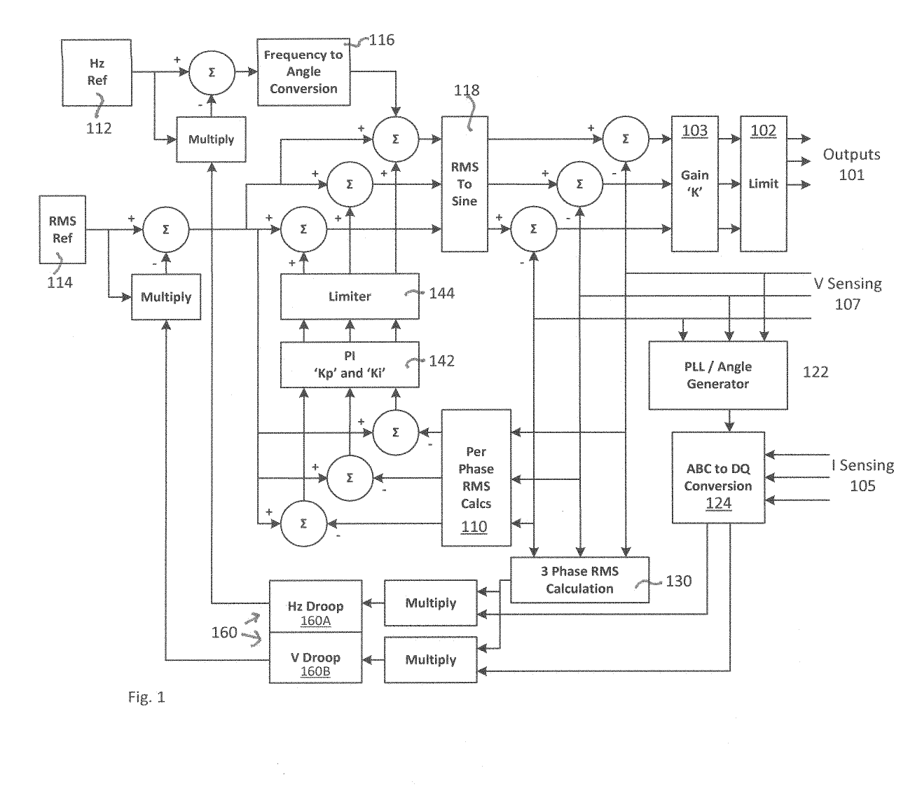

FIG. 1 schematically shows firmware components of an electronic power supply controller, in a microgrid system, which includes several innovative features.

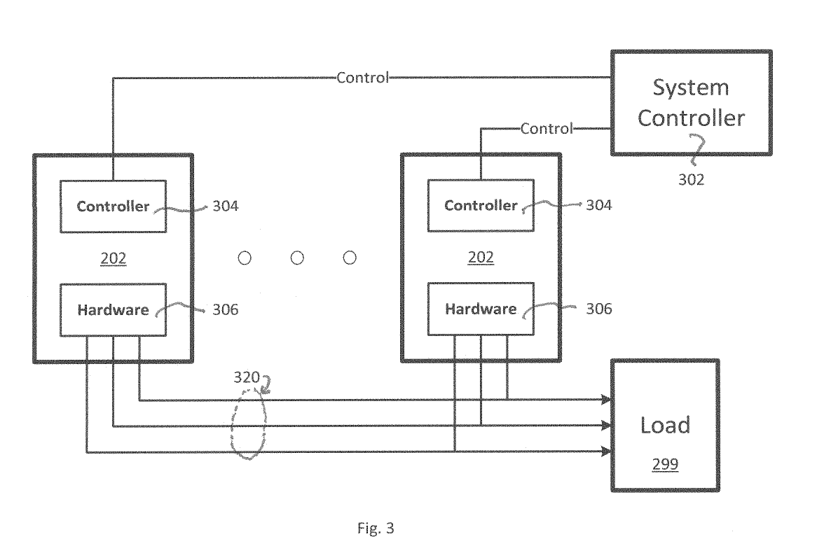

In this example, sensing of phase currents is shown as feedback inputs 105, and sensing of phase voltages is shown as feedback inputs 107. Command outputs to the hardware component of the electronic power converter are shown as per-phase command outputs 101. (The microgrid system controller, shown in FIG. 3, can load setpoint values into registers 112 and 114, as discussed below.)

The voltage feedback inputs are compared to time-varying reference values from the output of RMS-to-Sine converter block 118), scaled (in block 107), and passed through a limiter stage 102 to produce the outputs 101. This forms the inner loop of the control relationship. Note that this is a pure proportional loop, without any integration.

The current feedback inputs 105 go into an ABC to DQ conversion block 124, and the frequency of the voltage feedback inputs 107 is followed by a PLL/Angle generator block 122. This produces signals which are scaled (using the three phase RMS value of the voltage) and used to calculate the amount of frequency droop (in block 160A) and voltage droop (in block 160B).

The measured voltages 107 are also used (in block 110) to generate per-phase RMS values, which are fed (through PI stage 142 and limiter stage 144) to provide an outer control loop relation as discussed above. The PI stage 142 applies both a gain parameter Kₚ and an integration parameter K_{I}. Note that the three phase RMS value, as fed through V droop block 160B, is compared against the RMS reference value 114, so that the feedback relation for the RMS magnitude overrides that for the individual phase magnitudes.

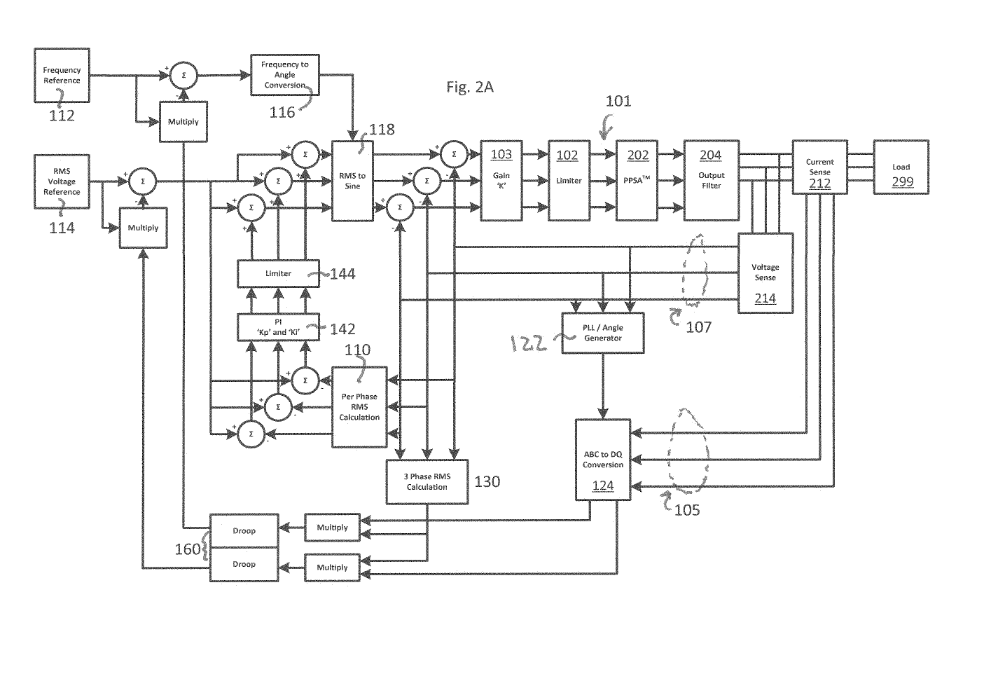

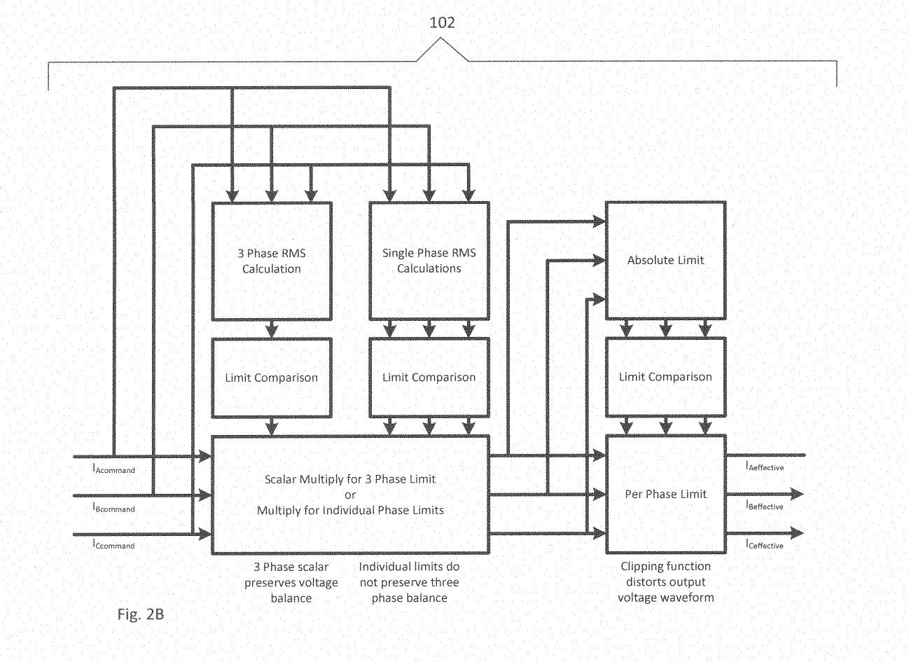

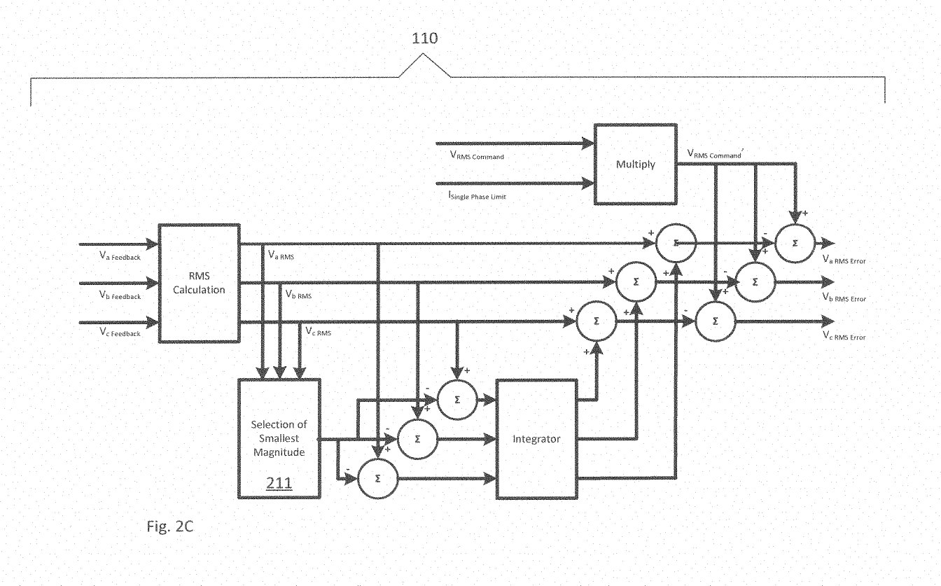

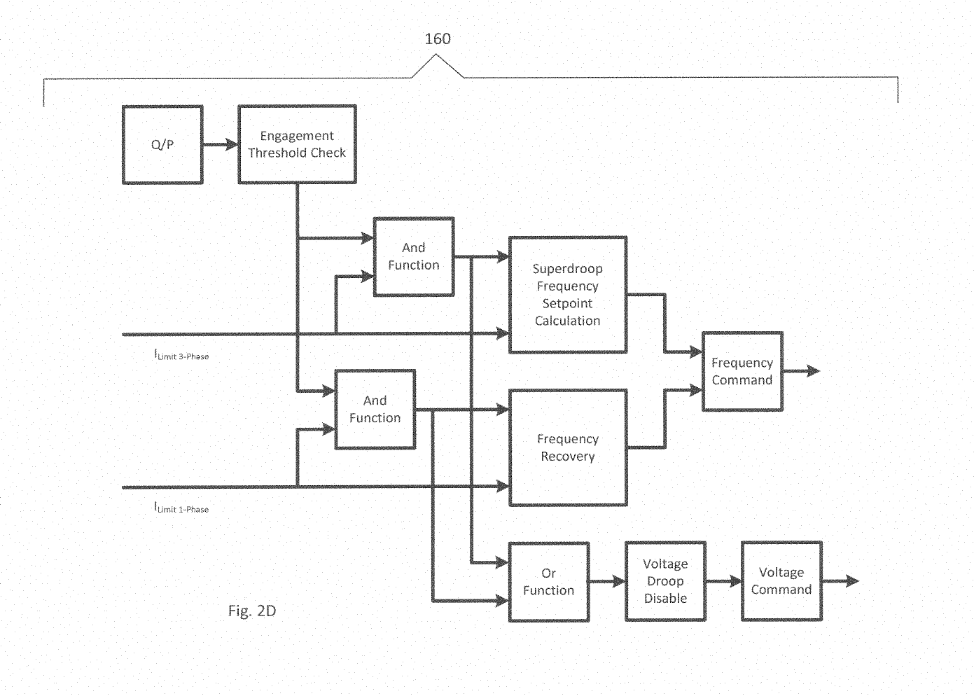

FIG. 2A shows how the firmware of FIG. 1 combines with hardware elements, in a sample embodiment. The command outputs 101 are provided to an electronic power converter 202, which in this case is shown as a power-packet-switching-architecture converter. Each such power converter will itself be connected to some source of power, e.g. a diesel or turbofan generator, batteries, or solar, hydro, or wind energy, for example, but for clarity these power sources are not shown here. The converter's output lines (three in this example) are filtered by block 204, and thence supply loads 299. Voltage sense unit 214 and current sense unit 212 provide the voltage feedback signals 107 and current feedback signals 105.

FIG. 2B shows an example of implementation of the limiter block 102 seen in FIGS. 1 and 2A.

FIG. 2C shows an example of implementation of the RMS calculation block 110, which was seen in FIGS. 1 and 2A. This also provides the voltage balancing function.

FIG. 2D shows an example of implementation of the droop stages 160, which were seen in FIGS. 1 and 2A.

FIG. 3 shows an example of how the system controller 302, whose operation is illustrated in the foregoing Figures, is combined with multiple power converter/supply units 202, and power supply lines 320, to form a complete microgrid. The power supply lines 320 are loaded by elements which are represented collectively here as a single unit 299. (In practice many units of various types would typically be connected to the supply lines 320.) Breakers and step-down transformers will typically define subdomains of the load, but the management of these subdomains is not particularly relevant to the operations described herein.

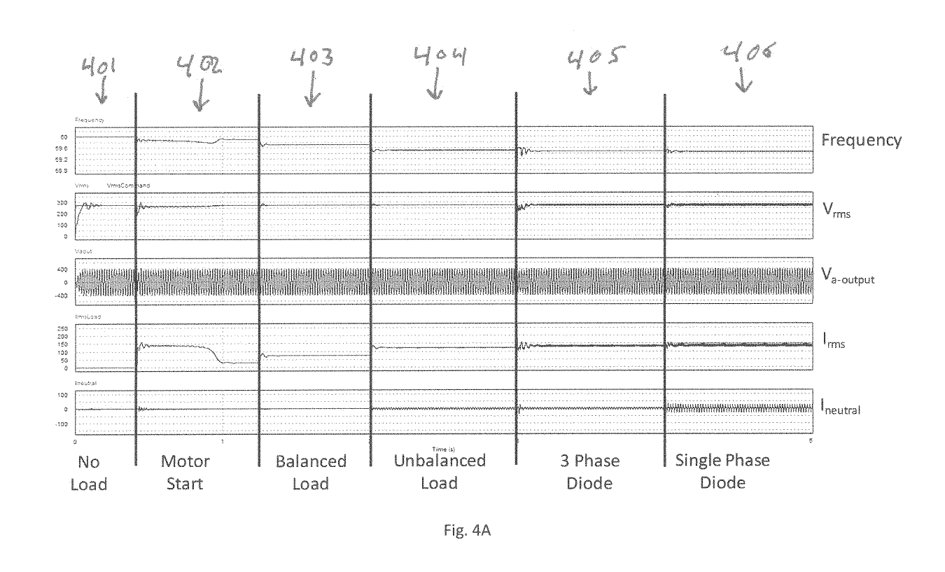

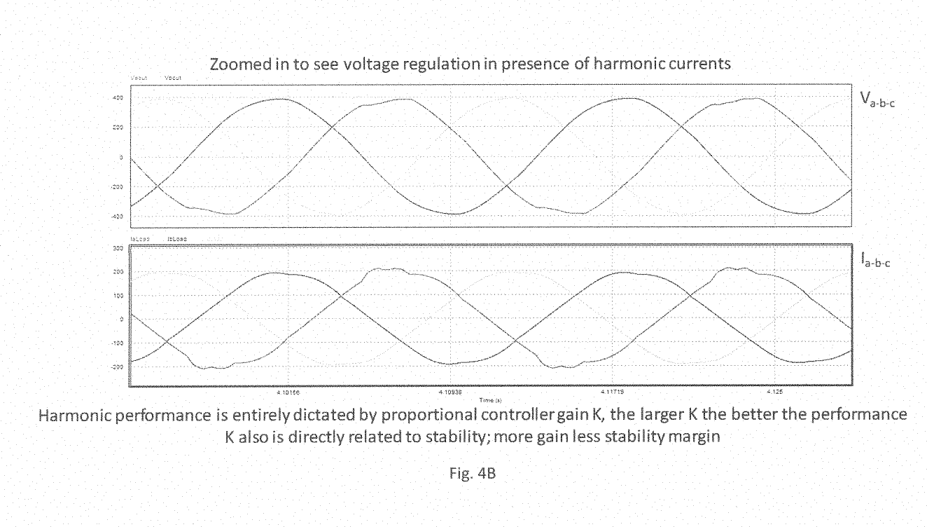

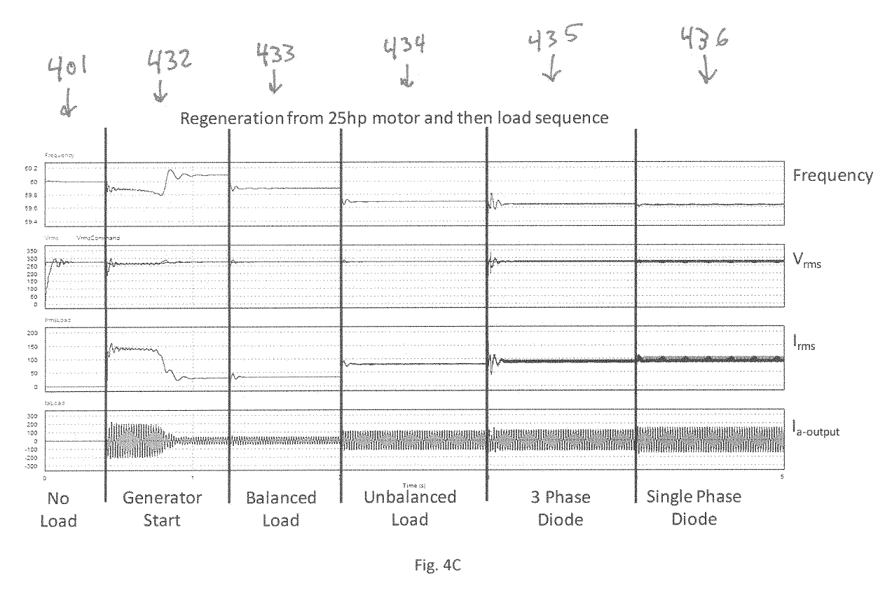

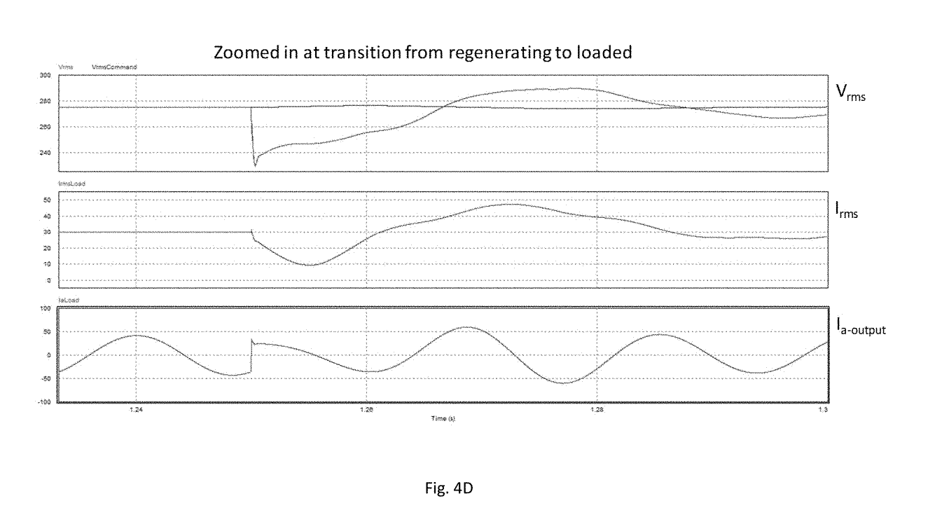

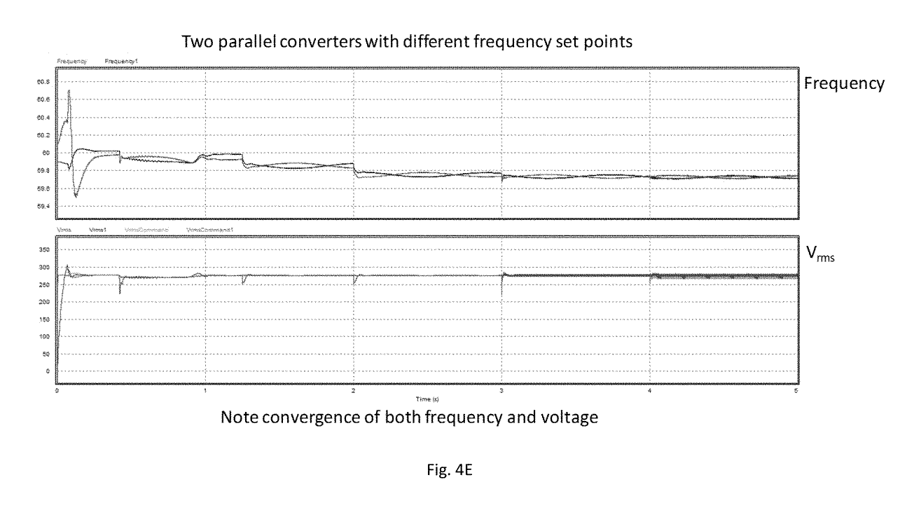

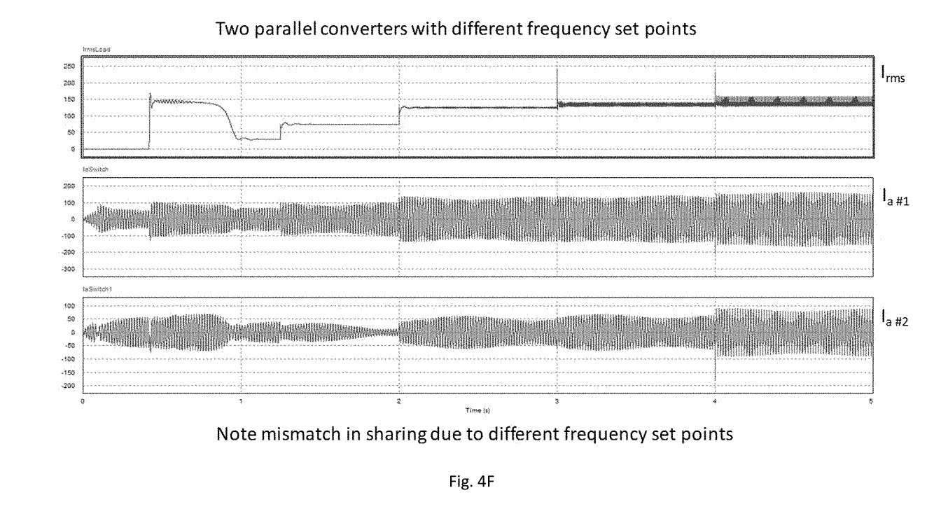

FIG. 4A is a five-line plot which shows operation of the power converter, operated by a controller like that shown in FIGS. 1-2D, as various load types are successively added. The values graphed include frequency, RMS voltage and current, a single-leg output voltage, and neutral current. Starting from a no-load condition (stage 401), we see: a motor start (stage 402); addition of a balanced load (stage 403); addition of an unbalanced load (stage 404); addition of a three-phase diode load (stage 405); and addition of a single phase diode (stage 406).

FIG. 4B is a graph of per-phase voltage and current, showing how the power converter responds to harmonic currents. Note that harmonic performance of the proportional controller is determined by the gain term; more gain means better performance. However, more gain also results in less stability margin.

FIG. 4C shows operation of the converter during a transition out of regeneration. The values graphed include frequency, RMS voltage and current, and a single-leg output current. Starting from a no-load condition (stage 401), we see: regeneration from a motor (stage 432); addition of a balanced load (stage 433); addition of an unbalanced load (stage 434); addition of a three-phase diode load (stage 435); and addition of a single phase diode load (stage 436).

FIG. 4D is a detail view of the transition from regeneration to loaded, during an expanded time scale corresponding to parts of stages 432 and 433 in FIG. 4C, which shows operation of the converter under various load types.

FIG. 4E is a plot of frequency and voltage, showing how two separate power converters in parallel, each operated by a controller like that illustrated in FIGS. 1-2D, reach convergence even when starting from different frequency setpoints. Note that this happens even without any intervention by a system controller like that shown in FIG. 3. However, FIG. 4F shows that such a mismatch in frequency setpoint can lead to asymmetrical sharing; it can be seen that the current on phase A of converter number 1 is well under 100 A, whereas that on phase A of converter number 2 is well over 100 A.

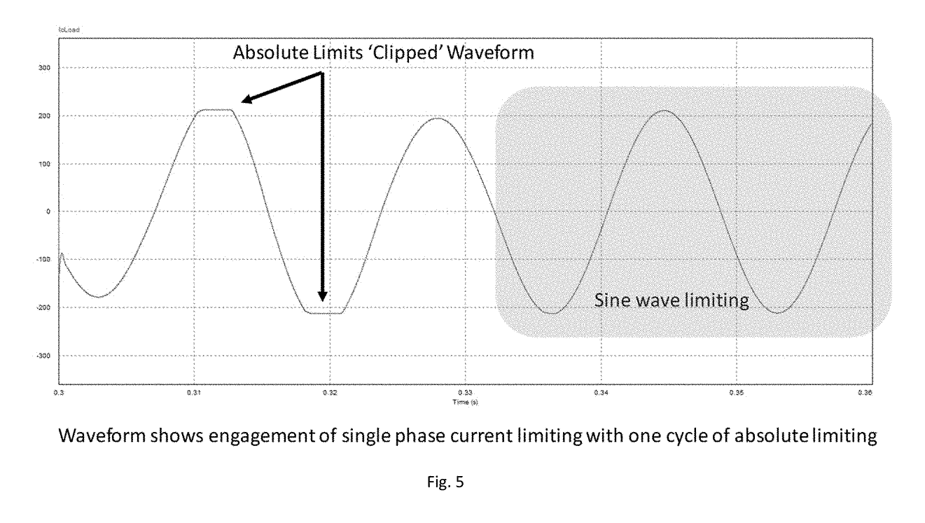

FIG. 5 shows the difference between sine wave current limiting, as taught herein, and conventional hard current limiting.

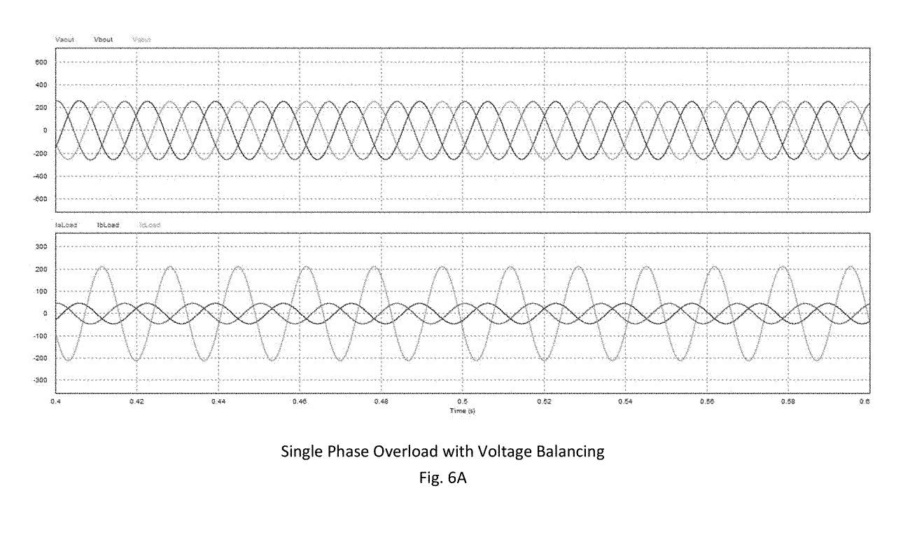

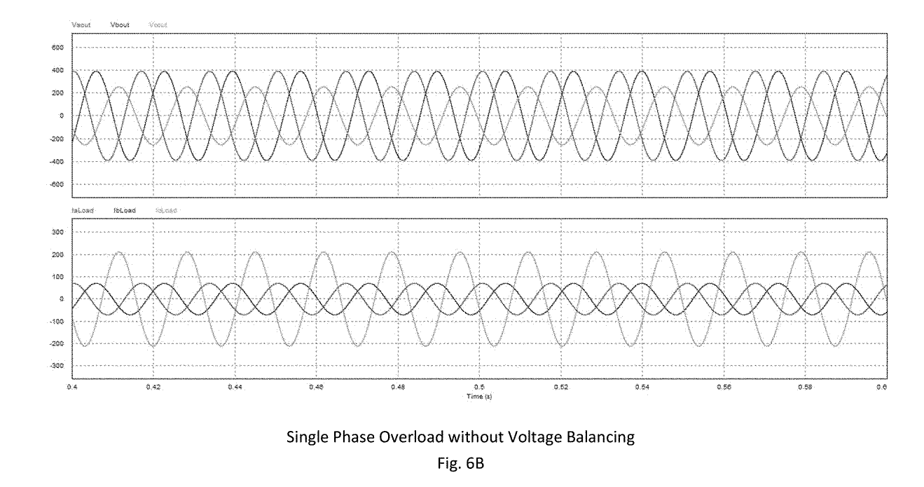

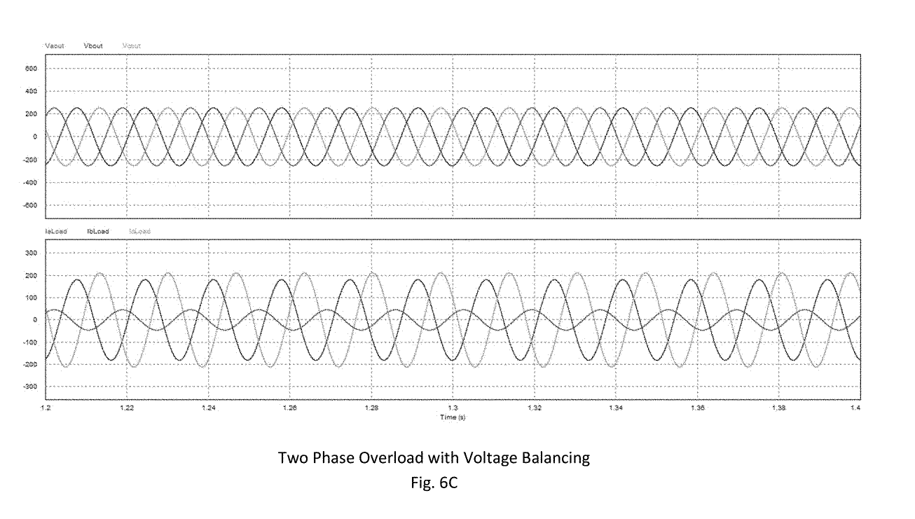

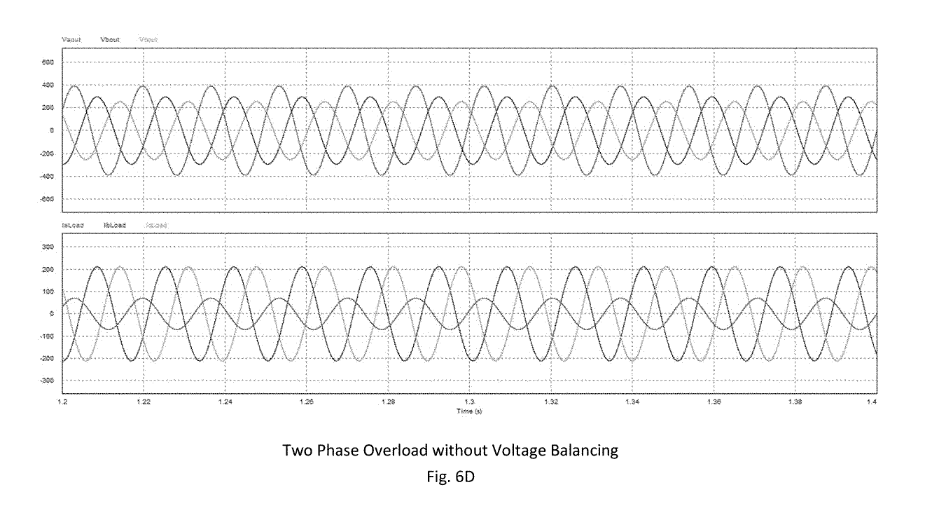

FIGS. 6A-6D show how voltage balancing, implemented as described herein, permits graceful compensation for single-phase or two-phase overloads.

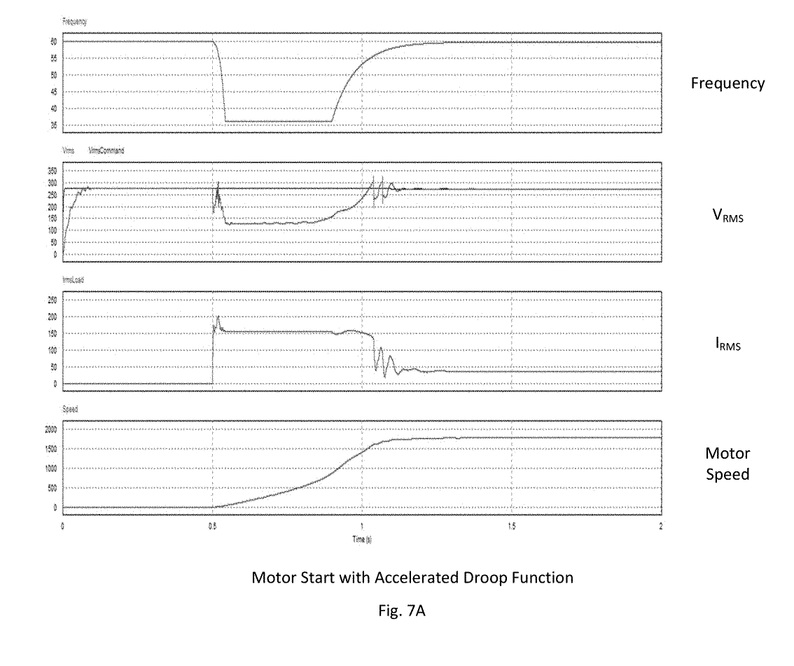

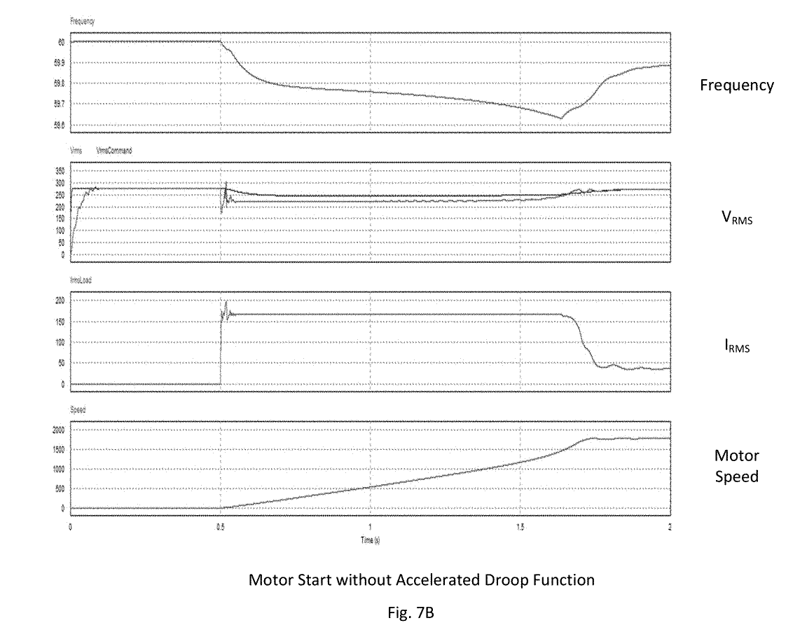

FIGS. 7A and 7B show how accelerated frequency droop is preferably used to enable faster recovery from an overcurrent due to line-starting a significantly large motor on the microgrid.

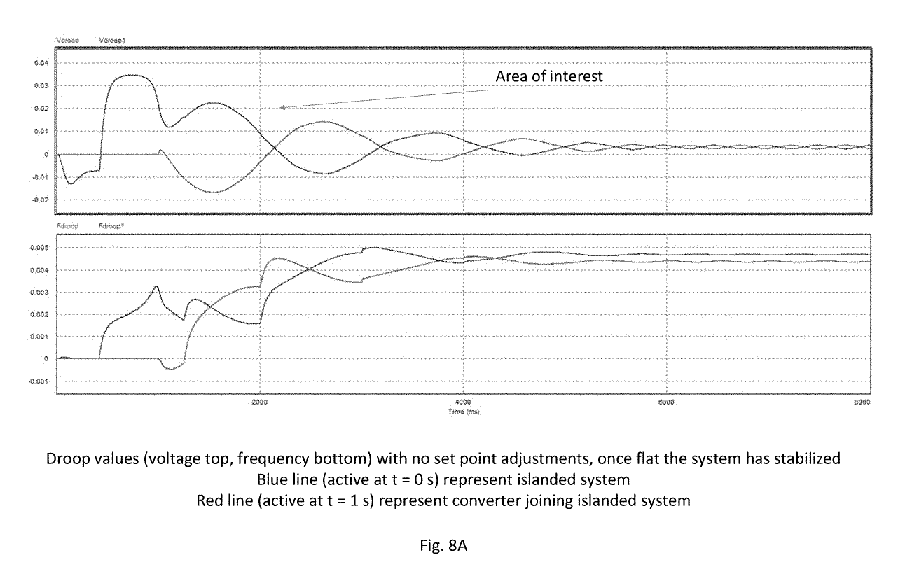

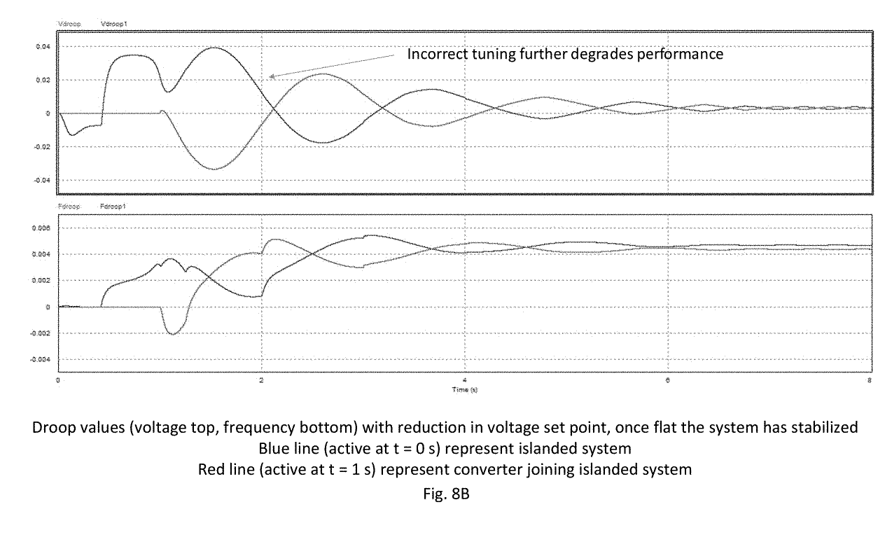

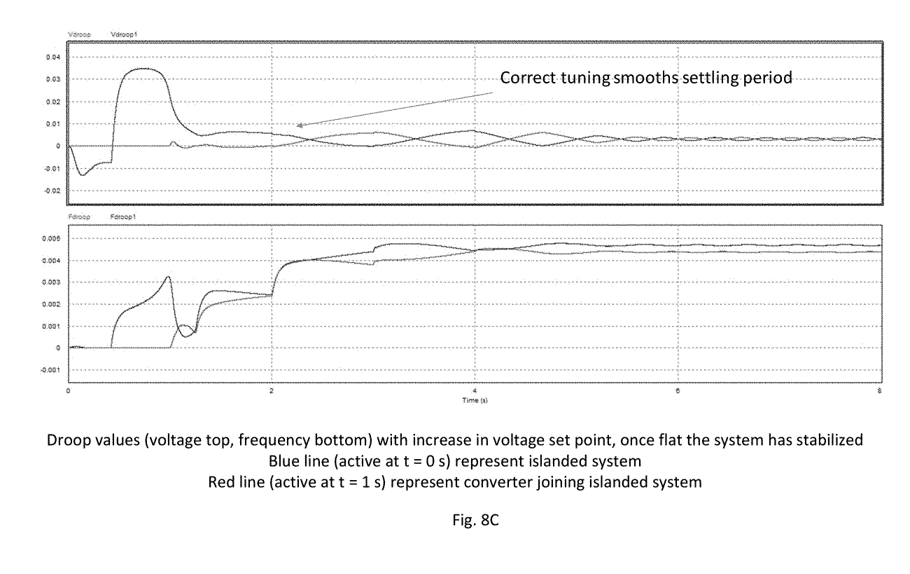

FIGS. 8A-8C show how the duration of transient instability is reduced, when an additional converter joins an islanded system, by modification of control parameters as described herein.

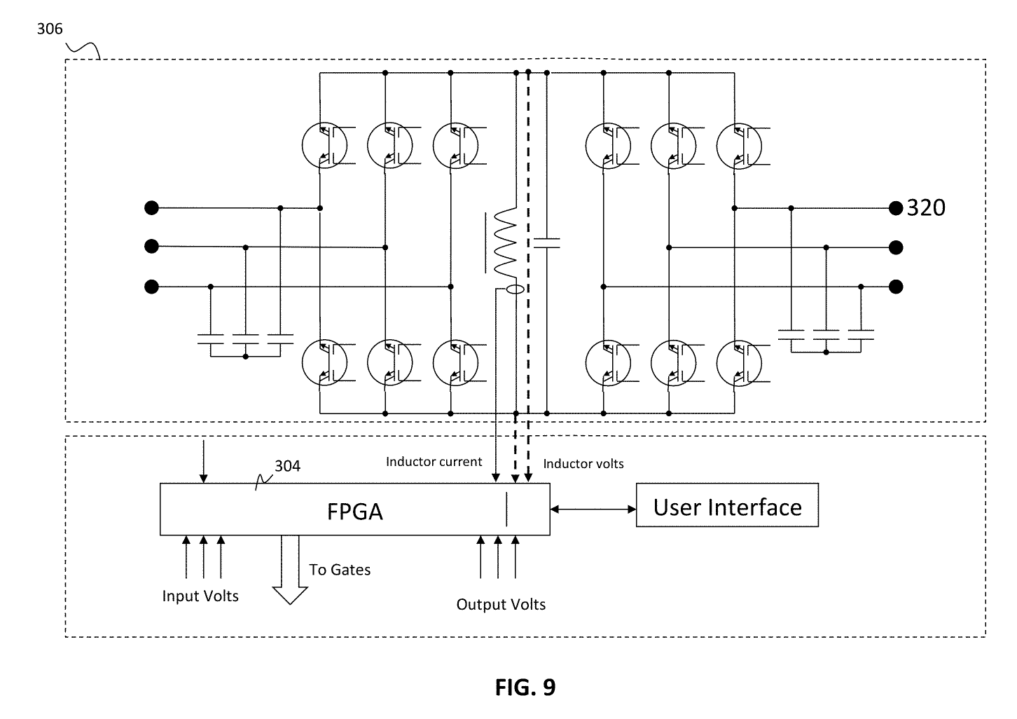

FIG. 9 shows an example of a power-packet-switching-architecture electronic power converter, including hardware components. Control of switch activations in the hardware elements 302 is performed, in this example, by a hardware controller 304 (implemented e.g. as a field programmable gate array) in accordance with the output commands 101 received from the control circuitry illustrated above. (The setpoints for that circuitry are preferably accessible to, and can be changed by, the microgrid system controller 302.)

This example is a PPSA electronic power converter with three phase legs on both its input and output ports. Such a configuration would be used, for example, where a three-phase diesel generator is the local power source. However, where the converter is interfacing to a battery, one of the phase legs on the left side of this drawing is unneeded, and a simpler converter configuration with a DC port can be used.

Microgrid Architecture with Proportional Control of AC Voltage (IPC-276)

The present application teaches, among other innovations, a microgrid architecture where power is supplied to the microgrid through one or more electronic power converters. The power converters are controlled using a control architecture in which the inner loop is a proportional control loop which can work directly with the AC voltage waveforms (and any additional harmonic content present on the output terminals of the converter). To overcome the inherent offset error in the proportional controller, RMS voltage compensation is wrapped around the proportional controller loop. The RMS voltage compensation loop includes integration, and can optionally be a “PI” (proportional/integral) or “PID” (proportional/integral/differential) loop. The integrated result from the voltage compensation loop is added back into the reference RMS value to create RMS command values, which are then converted to AC waveforms for use in the proportional controller.

A further innovative feature is that the RMS voltage compensation scheme is independently applied to each of the individual phases; this allows unbalanced loads to be connected to the microgrid without creating unbalanced output voltages.

### Combined Current Limiting (IPC-281)

When implementing a microgrid, current limiting must be employed to guarantee that excessive loads do not exceed the nameplate power/current ratings of the converter driving the microgrid. A simple instantaneous current limit can be applied on individual line-to-line phase pairs. However, this can lead to asymmetric reduction of the line currents and thus distortion (clipping) at peak current intervals.

To prevent such distortion, a combined RMS current limit can be applied. To do this, an RMS current associated with all 3 phases is evaluated. If the combined RMS current exceeds a combined RMS current limit threshold, then all 3 of the phase currents are limited proportionally by a scaling factor equal to the combined RMS current limit threshold divided by the combined RMS current. This results in symmetric reduction of the various line currents and minimal distortion of the line voltages within the microgrid.

Once the combined current limit has been applied, the simple instantaneous current limit can be applied to satisfy the previous constraints of nameplate power/current ratings. In a system with balanced loads, the combined RMS current limit threshold would nominally be set to guarantee compliance with these constraints, and no further current limiting (clipping) would be necessary. However, in a system with unbalanced loads, the application of the simple instantaneous current limit may still be necessary and may result in clipping of individual line currents with extremely unbalanced loads.

In an optional modification to the foregoing, which is believed to provide an improvement, clipping can be bounded within a transient response time period by further application of a single phase RMS current limit prior to the above clipping function. To do this, a single phase RMS current is evaluated. If the single phase RMS current exceeds a single current RMS limit threshold, then the associated individual line current is limited by a scaling factor equal to the single phase RMS current limit threshold divided by the single phase RMS current. This results in symmetric reduction of the individual line current with minimal distortion of the sinusoidal line voltage within the microgrid.

A complete application of these techniques would be as follows:

Stage 1—3 phase combined RMS current limit applied to all 3 phases

Stage 2—single phase RMS current limit applied to each phase individually

Stage 3—instantaneous current limit of individual currents (clipping)

A very simple diagram of the process would be:

I_{CMD}->Stage 1->Stage 2->Stage 3->I_{EFF}W;

where I_{CMD} is the commanded current, and I_{EFF} is the effective current after combined current limiting.

### Voltage Balancing

When an individual output phase is current limited, the phase voltage sags. The voltage sag is proportional to the limited current such that the limited current times the load impedance yields the output voltage of the current limited phase. This is typically managed using yet another innovative aspect of the disclosed microcontroller.

Voltage Balancing uses a control procedure which maintains balance (same magnitude) between the three phase voltages of a microgrid during individual phase(s) overcurrents.

During overcurrent events (faults, overloads) an individual phase will enter current limiting which results in a voltage sag on the current limited phase.

Voltage balancing sags (reduces) the phase voltages of the remaining phases such that all three phase voltages are again the same (balanced). Note, however, that the new balanced magnitude is not the same as original balanced magnitude.

First the scalar ratio used in limiting the single phase current is used to limit the commanded RMS voltage. The same ratio is applied: e.g. if the phase A current was limited to 60% of commanded value then the 3 phase rms voltage is limited to 60% of its value. This ensures that the voltage settled on by the controller is obtainable by all three phases.

The single phase RMS voltage feedback signals are compared with each other. The two largest voltages are then augmented such that the feedback term is increased by the difference between the measured phase and the smallest (current limited) phase. This feedback term increase is then integrated over time until the feedback signals are large enough to drive the error between all three phases to zero thereby stopping the integration process. At this point the phase voltages are balanced.

FIGS. 6A-6D show the effect of voltage balancing as described herein.

FIG. 6A shows the effect of a Single-Phase overload with Voltage Balancing. For contrast, FIG. 6B shows the effect of this condition without Voltage Balancing.

FIG. 6C shows the effect of a Two-Phase overload with Voltage Balancing. For contrast, FIG. 6D shows the effect of this condition without Voltage Balancing.

### Advantages

Voltage balancing ensures that loads connected across all three phases operate with a balanced input.

This is particularly advantageous to loads with active power electronic converters as they can overcome operational limitations imposed by the reduction in voltage when compared to passive power electronic loads.

Three phase motors can also benefit as they are intended to operate as balanced loads to maintain proper field excitation and rotation

The caveat of course is that if the overload is severe enough and the corresponding voltage collapse deep enough the motor could fall out of synchronization with the line frequency due to a lack of available input energy.

### Sine Wave Current Limiting

Current limiting is traditionally implemented after all the closed loop processing of a commanded signal has been completed but before that signal is converted to AC quantities.

A key component of the Ideal Power Microgrid Controller is its ability to work with sine wave quantities. The present application teaches that this combines synergistically with the use of Sine Wave Current Limiting.

Sine Wave Current Limiting is a over current protection procedure that works on AC quantities (sine waves) instead of DC quantities

This is especially synergistic and advantageous in the Ideal Power Microgrid Controller since it works on AC waveforms not DC waveforms.

Traditional limits are simple: if an input value exceeds the limit, the output is the limit. Using this sort of scheme on a sine wave results in the truncation of top of the sine wave creating a trapezoidal waveform while leaving the ‘sides’ of the sine wave intact. Since this is no longer a pure sine wave, harmonics and/or noise will be present.

The present application teaches, among other innovations, that Sine Wave Current Limiting is applied to all portions of the sine wave equally creating a current limited sine wave instead of a trapezoidal waveform on the output of the converter.

It has been found that a sinusoidal current limit can be generated by using the commanded current and an RMS limit. Commanded current of all three phases is converted to the instantaneous thee phase RMS current and single phase RMS currents

The RMS current limit is then divided by the RMS currents. If the ratios of are all greater than or equal to 1 then no limiting occurs. If the ration is less than 1, then all three commanded currents are multiplied by this ratio.

A similar scaling is then performed for the separate phases. If the limit over the current magnitude of phase n is less than 1, then that phase's commanded current is multiplied by this ratio.

Preference is given to the three phase limit over the single phase limits. In this implementation, single phase limiting is not engaged until the single phase RMS current is greater in magnitude by 2% than the three phase RMS current.

Once selected the three phase RMS current has to exceed the single phase value by 5% to transition to three phase current limiting.

While three phase current limited if the single phase RMS currents exceed the three phase RMS current by 5% the current limit will transition to single phase current limiting.

In both cases the transition to stop limiting is triggered by the commanded current being smaller in magnitude than the limited current. In this example, there is no ‘lock out’ period or ‘hold on’ timer. However, the hysteretic values given are adjustable, and are merely used as example; It would also be perfectly viable to implement with a 1% engagement threshold and a 2% disengagement threshold or any other numeric combination where the engagement threshold is less than the disengagement threshold and both are less than 100% in magnitude

Both the three phase and single phase sinusoidal limits are augmented with an absolute limit in a two stage process. The absolute limit results in clipping of waveform but prevents overcurrent on short term basis.

There is potential to engage the absolute limits during transitions between sinusoidal current limits

Potential also exists to engage during a light single phase overload where three phase limit is not active and single phase overload is not large enough to exceed the 2% threshold for engagement above the three phase RMS value

Resultant distortion is minimal due light overload condition.

Sine Wave Current Limiting has the advantage of preserving the output voltage waveform quality.

This control procedure is fast responding and provides robust operation for multiple overloads conditions across all three output phases.

Using absolute limits as a second stage ensures that all overloads are captured but puts the emphasis on Sine Wave Current Limiting.

### Accelerated Droop

Line-starting motors is challenging to the utility network. The “Inrush” current, when a motor is started from line voltage, can exceed the nameplate values by 5× or more. Moreover, these inrush currents are almost purely reactive. The high-current condition can persist for a second or longer.

Conventional induction motor controllers (VFDs) typically vary the voltage with respect to frequency for more effective motor control. Once the motor has come up to speed, the synchronized motor speed is directly related to excitation frequency (or, for small motors which are not separately excited, line frequency less a small amount of slippage).

The present application teaches a microgrid architecture with an advanced operational method (referred to herein as “superdroop”) which enables motor starting on a microgrid above the nominal current capability of the microgrid.

Superdroop is initiated when the reactive power to active power ratio internally calculated by the converter to exceed 1, this would be indicative of a motor start and also locks out three phase faults from enabling sustained Superdroop operation.

Superdroop plays on the voltage sag inherent in current limiting by drooping frequency in response to current limiting. Note that nominal frequency droop cannot be applied as it droops with respect to active power and active power is not a prime component of a line started motor. (Line started motors are primarily consumers of reactive power.)

The drawback to ‘Superdroop’ is that the balance of equipment on the microgrid will experience a frequency and voltage sag. However, this is generally preferable to collapse of the microgrid network.

Superdroop motor starts are a two stage process. The goal of the first stage is to get the motor into synchronization with the microgrid at a lower frequency

During this time the frequency of the microgrid is preferably drooped in direct proportion to the amount of current limiting. I.e. if the sine wave limiting is at 80% (output is 80% of command) then the microgrid frequency set point is set (in this example) to 80% of nominal.

Voltage command is not drooped as the voltage has sagged due to the overcurrent limiting

As the motor approaches synchronization with the microgrid frequency, the reactive power to real power ratio will shift and the current limiting will transition from a three phase limiting to individual phase limiting. At this point the controller starts the frequency recovery process and steadily brings the frequency up to the nominal operating point of the microgrid. During this transition period the microgrid will stop being current limited and the microgrid controller will transition to normal operation, drooping both frequency and voltage with respect to the connected loads.

Sophisticated motor control units (known as “VFDs”) vary the voltage with respect to frequency, in a constant V/Hz ratio, for more effective motor control during startup. The architecture described herein results in simultaneous droop of frequency and voltage with somewhat similar benefits. Of course, the balance of equipment on the microgrid experience a frequency and voltage sag. However, this cost, if tolerable, helps avert a worse consequence, namely an eventual collapse of the microgrid network.

This accelerated droop operation advantageously enables a microgrid controller to start larger motors than it would otherwise be able to start.

This accelerated droop operation also advantageously enables a faster start up time for motors on a microgrid.

This accelerated droop operation also advantageously truncates disturbances on the network during such a startup period.

Impact on other loads on the microgrid can be limited by imposing a limit on droop. For example, the minimum voltage is currently held to 60% of nameplate. For example, for a 480V 60 Hz system this would be 288V at 36 Hz. This reduces power to a resistive load by almost two-thirds.

For a 150 A converter this limit would enable starting of motors with nameplate ratings of 35 A to 50 A. By contrast, the expected limit with normal allowances should be 21 A to 30 A. This is a significant improvement.

More extreme droop is technically feasible and would allow for additional starting capability, while impairing the operation of other equipment already connected to the microgrid.

According to some but not necessarily all embodiments, there is provided: A method of operating a microgrid, comprising: measuring the output of an electronic power converter against a varying reference value which has a sinusoidal dependence on time; and in accordance with the measuring step, generating a first output command for the converter, using a pure proportional control relation with no integration component; and using an additional control relation to adjust the output command, in dependence on the magnitude of a measured electrical value, to remove offset error and thereby generated an adjusted output command for each phase; and initiating a current limiting operation, which limits current to a varying value which also has a sinusoidal dependence on time, if the measuring step shows an overcurrent value; and if one or two phases exhibit fault conditions reducing the adjusted output command of the other phase or phases, to thereby restore the balance of the different phases; and sending the adjusted output command to the converter as a control input.

According to some but not necessarily all embodiments, there is provided: A method of operating an electronic power converter, comprising: measuring an output of the converter with respect to a varying reference value which has a sinusoidal dependence on time; and in accordance with the measuring step, generating an output command for the converter, using a pure proportional control relation with no integration component; and using an additional control relation to adjust the output command, in dependence on the magnitude of a measured electrical value, to remove offset error and thereby generate an adjusted output command; and sending the adjusted output command to the converter.

According to some but not necessarily all embodiments, there is provided: a method of operating an electronic power converter, comprising: controlling power output in accordance with voltage and/or current feedback; wherein the power output is controlled, at the lowest level, by a proportional control relation, with no integration component, which provides an output command for the converter; and wherein an additional control relation, which includes an integral term, adjusts the output command to remove offset error.

According to some but not necessarily all embodiments, there is provided: a method of operating an electronic power converter, comprising: measuring at least one output of the converter with respect to a varying reference value which has a sinusoidal dependence on time; and controlling operation of the converter in partial dependence on the measuring step, while initiating a current limiting operation if the measuring step shows an overcurrent value; wherein the current limiting operation limits current to a varying value which also has a sinusoidal dependence on time.

According to some but not necessarily all embodiments, there is provided: a method of operating a microgrid, comprising: using the difference between an instantaneous output measurement of an individual phase and a varying reference value which has a sinusoidal dependence on time, to produce a command value for transmission to at least one electronic power converter which supplies power to the microgrid; modifying the command value using a comparison of values for measured output and commanded output, to thereby produce a modified command value; controlling operation of the electronic power converter in partial dependence on the modified command value; and further comprising a balancing operation which, when one or two phases exhibit fault conditions, reduces the commanded voltage of the other phase or phases, to thereby restore the balance of the different phases.

According to some but not necessarily all embodiments, there is provided: a method of operating a microgrid using multiple power sources and at least one electronic power converter, comprising: operating the microgrid from a first power source; and starting to transfer power from a second power source into the microgrid, while the first power source also continues to transfer power; wherein the first and second power sources are both operated in dependence on output commands which are sent from a higher-level controller which includes at least first and second control loop relationships; wherein initial parameters for the first and second control loop relationships are set to values which would cause the power transfer elements to output an overvoltage, if not for the operation of the first and second control loop relationships.

According to some but not necessarily all embodiments, there is provided: A method of operating a microgrid using an electronic power converter, comprising the actions of: a) automatically detecting, using observed reactive power loads on a local power network, initiation of a line-starting inrush current which has transiently overloaded the power converter; and b) when the automatically detecting operation detects such a line-starting inrush current, immediately and temporarily lowering the frequency of power supplied to the microgrid, independently of other control relationships, to the minimum acceptable values, to thereby accelerate motor synchronization and return to stable operation; and c) returning to normal operation of the power converter.

According to some but not necessarily all embodiments, there is provided: A microgrid, comprising: electrical power wiring; one or more electronic power converters, each connected to supply power to the electrical power wiring; and a microgrid system controller, which sends output commands to the electronic power converters while performing the method in any of the preceding paragraphs.

According to some but not necessarily all embodiments, there is provided: A microgrid, comprising: electrical power wiring; multiple power-packet-switching-architecture electronic power converters, each connected to supply power to the electrical power wiring; and a microgrid system controller, which sends output commands to the electronic power converters while performing the method in any of the preceding paragraphs.

According to some but not necessarily all embodiments, there is provided: Power converters, and microgrids driven by such a power converter, in which the converter is controlled by a proportional controller which operates directly on AC waveforms, preferably without conversion to a DC type signal; preferably with use of voltage compensation to remove inherent error of proportional controller; and preferably with use of individual phase RMS voltages in the voltage compensation, to allow for normal operation under any load condition. Undervoltage of one or two phases is automatically compensated by adjusting the voltage of all phases, to retain balance. Line-starting of a motor load is automatically detected, and frequency droop is driven, apart from the other control relations in the system, to complete the line-starting operation as quickly as possible.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

For one example, the operation of the “superdroop” method, as described above, can be modified when more motors are operating on a microgrid. One example of such a modification would be to raise the minimum droop value in dependence on whether another motor is already operating. Another example would be to impose a time constant on the power frequency change at the start of superdroop operation.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned. Specifically, the claims are intended to cover: Systems, methods, devices, and/or components according to any portion of the description herein, insofar as enablingly disclosed herein; Each and every novel structure, device, method for fabrication, method for design, method for use, business method, or other novel method or structure disclosed herein; All synergistic combinations and sub-combinations of devices, methods, and implementations as enablingly described herein.

Those of ordinary skill in the relevant fields of art will recognize that other inventive concepts may also be directly or inferentially disclosed in the foregoing. NO inventions are disclaimed.

1. A method of operating an electronic power converter, comprising:
measuring the output of an electronic power converter against a varying reference value which has a sinusoidal dependence on time; and
in accordance with the measuring step, generating a first output command for the converter, using a pure proportional control relation with no integration component; and using an additional control relation to adjust the output command, in dependence on the magnitude of a measured electrical value, to remove offset error and thereby generated an adjusted output command for each phase; and
initiating a current limiting operation, which limits current to a varying value which also has a sinusoidal dependence on time, if the measuring step shows an overcurrent value; and
if one or two phases exhibit fault conditions reducing the adjusted output command of the other phase or phases, to thereby restore the balance of the different phases; and
sending the adjusted output command to the converter as a control input.

2. The method of claim 1, wherein the additional control relation is a PI control relation.

3. The method of claim 1, wherein the current limiting operation is applied to combined current, and also, separately, to the individual single phases.

4. The method of claim 1, wherein the additional control relation is a PID control relation.

5. The method of claim 1, wherein the current limiting operation is applied to combined current, and also, if the combined current is within bounds, to the individual single phases.

6. The method of claim 1, wherein the current limiting operation is supplemented by an absolute limit, which protects against failure of the current limiting operation.

7. The method of claim 1, wherein the measuring step comprises measuring the voltage of at least one phase.

8. The method of claim 1, wherein the converter is a power-packet-switching converter.

9. The method of claim 1, wherein the magnitude is a root-mean-square value.

10. The method of claim 1, wherein the possible fault conditions include overcurrent and undervoltage.

11. A method of operating an electronic power converter, comprising:
measuring an output of the converter with respect to a varying reference value which has a sinusoidal dependence on time; and
in accordance with the measuring step, generating an output command for the converter, using a pure proportional control relation with no integration component;
and using an additional control relation to adjust the output command, in dependence on the magnitude of a measured electrical value, to remove offset error and thereby generate an adjusted output command; and
sending the adjusted output command to the converter.

12. The method of claim 11, wherein the additional control relation is a PI control relation.

13. The method of claim 11, wherein the additional control relation is a PID control relation.

14. The method of claim 11, wherein the measuring step comprises measuring the voltage of at least one phase.

15. The method of claim 11, wherein the converter is a power-packet-switching converter.

16. The method of claim 11, wherein the magnitude is a root-mean-square value.

17. A method of operating an electronic power converter, comprising:
controlling power output in accordance with voltage and/or current feedback;
wherein the power output is controlled, at the lowest level, by a proportional control relation, with no integration component, which provides an output command for the converter;
and wherein an additional control relation, which includes an integral term, adjusts the output command to remove offset error.

18. The method of claim 17, wherein the additional control relation is a PI control relation.

19. The method of claim 17, wherein the additional control relation is a PID control relation.

20. The method of claim 17, wherein the measuring step comprises measuring the voltage of at least one phase.

21-61. (canceled)
